(19) United States
(12) Patent Application Publication
(10) Pub. No.: US 2022/0397596 A1
(43) Pub. Date: Dec. 15, 2022

(54) SYSTEM AND METHOD FOR MULTIPLEXING AND DEMULTIPLEXING RF SIGNALS USING A PLURALITY OF RF-TO-OPTICAL ANTENNAS

(71) Applicant: NuCrypt, LLC, Park Ridge, IL (US)

(72) Inventor: Gregory S. KANTER, Chicago, IL (US)

(21) Appl. No.: 17/841,108

(22) Filed: Jun. 15, 2022

Related U.S. Application Data
(60) Provisional application No. 63/210,609, filed on Jun. 15, 2021.

(51) Int. Cl. G01R 29/08; H04J 14/02

(52) U.S. Cl. CPC G01R 29/0871; H04J 14/02

(57) ABSTRACT

A system for processing and measuring radio frequency (RF) signals is described. The system uses a plurality of RF-to-optical antennas (ROAs). The ROAs can be configured to measure different characteristics of an RF signal such as different frequency bands or different polarizations. The ROAs are probed with an optical source, and the ROAs measured are determined by the wavelength or wavelengths of said optical source. A wavelength division multiplexer (WDM) separates the incoming optical wavelength or wavelengths so that a different wavelength can probe each ROA. It is possible to reflect the ROA-modulated optical signal after propagating through the ROA so as to produce a larger modulation on the optical signal. Here, the WDM also serves to combine the optical wavelengths so that a single fiber serves as the optical interface to the ROAs. The device can be configured to operate over a wide range of RF spectra.

### FIELD OF THE INVENTION

The field of the invention is radio frequency (RF) signal measurement, as commonly used for wireless communications, radar, and navigation purposes.

### BACKGROUND

Wireless RF signals are ubiquitously used in applications including wireless communications, radar, and navigation. An electrical antenna is typically used to pick up the signal. The signal captured by the antenna is usually transported via an electrical waveguide such as an electrical cable to subsequent RF components. The antenna, electrical cable, and RF components are ideally designed to have matching impedances, most typically 50 ohms, which creates a design constraint that can limit performance. Other components in the RF receiver chain may be amplifiers, down-conversion stages, filters, and electrical distribution cable. In some cases, the antenna may be far from subsequent processing electronics, a configuration sometimes called antenna remoting, and long lengths of electrical cable may be required to distribute it from the antenna to the processing electronics. However, RF carrier frequencies tend to have significant attenuation in electrical cable. So, it is advantageous if the signal is first down-converted to a lower RF frequency which allows for lower cost and lower loss electrical cable. However, the down-conversion stage is complex, for instance requiring a local oscillator, and, especially if the antenna is in an awkward position like the mast of a ship, it can be advantageous to remove complexity near the antenna. This creates a design trade-off as to where to put the down-conversion stage.

One way to address this problem is to use RF-photonic components that convert the RF signal into an optical signal which is relatively easy to transport over fiber optical cable which has low loss, high bandwidth, low weight, and no electro-magnetic interference. For instance, an electrical antenna can feed its signal to an optical modulator (or alternatively it can be fed into a semiconductor laser to directly modulate the laser's current) in order to modulate the RF signal onto the optical signal. These additional components may require electrical power or other electrical control signals and because of their footprint or interference issues may be inconvenient to put near the antenna. As the antenna and optical modulator are discrete components connected by RF cable, impedance matching issues constrain the system design.

RF-to-optical antennas (ROAs) have been proposed which directly modulate an optical signal with a wireless RF signal. For example, an antenna can be integrated with an optical modulator and coupled directly to the modulator electrodes [U.S. Pat. No. 5,963,034], thereby avoiding electrical cable and RF connections. This miniaturizes the system and can give more design flexibility due to fewer impedance matching constraints. The optical signal can be fed to the ROA through a fiber optical cable, and the RF-modulated optical signal can be sent back via fiber to a processing station eliminating extra components near the antenna. This allows simple and small antennas to be remoted to distant sites over convenient optical cable. For our purposes any integrated means of modulating an optical signal with a wireless RF signal will constitute an ROA, even if the mechanism for modulation is not a traditional antenna, such as via the use of periodic poling [U.S. Pat. No. 5,267,336] or a diaphragm transducer [U.S. Pat. No. 5,280,173].

An ROA is often polarization sensitive, responding with much greater efficiency to one RF polarization than to another. There are times, however, when the incoming polarization is not controlled or is unknown and thus it is desirable to measure more than one polarization orientation. Other times two orthogonal polarizations may carry different signals, a situation known as polarization multiplexing. In either case, using multiple antennas mounted in different physical orientations allows both polarizations to be efficiently detected and the desired signal can then be reconstructed using subsequent signal processing.

Another problem for RF receivers is the limited bandwidth (range of frequencies over which it operates) of a given antenna. The antenna center frequency and bandwidth are dictated by its design (geometry) and its size. Some antennas can have limited tunability but this is challenging and comes with trade-offs. George [U.S. Pat. No. 7,627,250 B2] used two separate antennas in a transmit/receive system where one antenna transmitted at one frequency and a second antenna received at a different frequency. This design allows for low interference between the transmit and receive signals, but does not address the limited bandwidth of a given receive antenna. This system used electrical-to-optical (E/O) and optical-to-electrical (O/E) converters near the antenna to convert between the RF and optical domains, which makes the system electrically active. The transmit and receive channels each have their own fiber in/out (I/O) cables.

Efficient ROAs that modulate the optical signal strongly with weak RF signals can have low frequency bandwidths, such as ˜10% of the peak RF carrier [Wijayanto, Yusuf Nur, Hiroshi Murata, and Yasuyuki Okamura. “Electrooptic Millimeter-Wave-Lightwave Signal Converters Suspended to Gap-Embedded Patch Antennas on Low-k Dielectric Materials.” IEEE Journal of Selected Topics in Quantum Electronics 19.6 (2013): 33-41.]. It is desirable to be able to detect RF signals over a greater bandwidth, allowing a larger range of incoming RF frequencies to be detected.

ROAs can be realized in a compact optical sub-system, such as a photonic integrated circuit (PIC). One can imagine having multiple ROAs on such a PIC. However, if each ROA has a separate fiber optic input/output (I/O) port or if each ROA needs an independent subsequent detection system, then this direct method of expanding the range of RF frequencies the system can respond to can become cumbersome and bulky.

Some ROAs use modulators that require a bias signal, such as Mach-Zehnder Interferometer (MZI) intensity modulators. It would be beneficial if an electrical bias signal was not required so as to keep the ROA fully passive and less prone to interference. MZIs can also be designed with an asymmetric delay to allow the optical frequency to adjust the bias [Zhang, Jiahong, et al. “Broad-Band Integrated Optical Electric Field Sensor Using Reflection Mach-Zehnder Waveguide Modulator.” Fiber and Integrated Optics 36.4-5 (2017): 157-164], which means that the laser wavelength can be tuned to control the bias, although this would be challenging to implement with more than one antenna. This prior art used a reflective film to back-reflect the optical signal twice through the antenna-coupled modulation section which in principle can improve the modulation depth and reduce the number of fiber I/O's by reusing the input fiber port (in transmission) as the output fiber port (in reflection). However, it is difficult to scale the method used to multiple ROAs.

Some antenna remoting systems convert the phase applied at the signal modulator and convert it to a detectable amplitude using a phase-to-amplitude converter like a passive asymmetric Mach-Zehnder Interferometer (AMZI) [Urick, Vincent J., et al. “Phase modulation with interferometric detection as an alternative to intensity modulation with direct detection for analog-photonic links.” IEEE transactions on microwave theory and techniques 55.9 (2007): 1978-1985.] Such a method has high gain and benefits from the option of differential detection which can subtract out unwanted technical noise. Like an MZI the AMZI is sensitive to an internal phase or the exact wavelength of the optical source, which makes it difficult to use a single AMZI for more than one antenna channel. It would be beneficial if just one AMZI could operate on multiple channels. Additionally, AMZI's naturally have about an octave of bandwidth, restricting the potential RF frequency range of a system using said AMZI. It would be beneficial to allow a larger RF frequency range.

Another kind of phase-to-amplitude conversion system is to use a photonic down conversion system such as [Pagán, Vincent R., Bryan M. Haas, and T. E. Murphy. “Linearized electrooptic microwave downconversion using phase modulation and optical filtering.” Optics express 19.2 (2011): 883-895.], which both converts the phase-modulated signal into an amplitude-modulated signal and reduces the carrier frequency from the received RF center frequency to a lower intermediate frequency.

What is needed is a system or method to use integrated ROAs that operate with high efficiency in converting RF signals at the antenna into a received RF signal at a processor where fiber optic cable connects the ROA and processor. Multiple ROAs should be probed with a small number of fiber input/outputs, including a single fiber input/output, with the ROAs optionally designed to optimally receive different types of signals including different RF frequencies or different RF polarizations. The RF spectral response of multiple antennas can be non-overlapping or partially overlapping, expanding the frequency range over which RF signals can be measured. Ideally the ROAs should not use any bias signal or even have any electrical inputs at all (fully electrically passive). The desired functions should be achievable with convenient equipment and ideally a minimal number of additional components.

### SUMMARY

We describe a system and method for measuring multiple wireless RF signals using RF-to-optical antennas (ROAs). Without loss of generality, we assume an implementation in a photonic integrated circuit (PIC) though other configurations are possible using similar design concepts. Multiple ROAs are designed into the PIC. The ROAs are inherently in different physical locations (e.g., on the plane of the PIC) and can also be in different physical orientations so as to detect different RF polarizations, or be of different designs including different physical sizes so as to efficiently detect different RF frequencies. The optical signals are carried into and out of the system by a number of optical fibers that are typically less than the number of ROAs on the PIC, including the use of just a single optical fiber.

The optical signal probing the ROAs are modulated with the incoming RF signal and can be reflected back through the ROA after being modulated. The reflection happens at an appropriate distance that controls the delay between the optical signal modulated in the forward direction and the RF signal to the ROA so that the ROA modulates the RF signal onto the optical signal twice (in-phase) thereby increasing the modulation efficiency. This also leverages the same fiber as both the input and output port, provided there is some means of separating the input and output directions such as the use of an optical circulator, which reduces the burden of fiber coupling and reduces the number of separate optical fibers in the fiber cable.

The PIC contains a wavelength division multiplexer (WDM). The WDM splits different optical wavelengths traveling on a given fiber into multiple outputs of different wavelength. Each wavelength can then be modulated by a different ROA. In this way all the ROAs or some subset of them can be measured by controlling the input wavelengths. This does not require an optical switch either inside or near the PIC and thus no control electrical signal needs to be sent to the PIC. If the optical signal is back-reflected through the ROA then the WDM is used in reverse to re-multiplex the modulated optical signals from the selected antennas and send them backwards. An optical circulator can separate out the forward and backward propagating optical signal, so as to send the ROF modulated signals to the remote detection system.

Each ROA ideally operates using a phase modulator so that no electrical bias signal is required to bias the modulator. This requires a phase-to-amplitude conversion system, which can be realized for instance using remote-side (off chip) interferometers, remote-side modulators driven by an electrical local oscillator to perform photonic down-conversion, or optical local oscillators to enable coherent detection. Each ROA can be designed to respond to different properties of an RF signal, such as having responsivity at different RF frequencies or in different RF frequency bands, responding to different RF polarizations, or responding to different spatial positions of the RF signal. In this way the ROAs being probed correspond to the properties of the RF signal being measured, which can include different RF signals such as when RF signal are frequency or polarization multiplexed. An RF lens can be used to focus the incoming RF signal on the ROAs, which also allows the different ROA locations to translate into information about the angle-of-arrival of the RF signal.

One excellent candidate for fabricating the PIC is thin film lithium niobate material. Such a material can be a very efficient ROA since it has small dimensions and a high electro-optic coefficient. Additionally, the properties of the material allow functions like a WDM to be realized in a small space. The use of a Bragg grating in the material can realize reflector, and such a grating can be made in thin film lithium niobate. That is, all the functions of the invention can be realized with high quality in this material.

In one implementation multiple wavelengths generated by one or more tunable lasers selects which subset of antennas to measure, including the case where all the antennas are measured. A photonic down-conversion system (PDC) with a single local oscillator (LO) can down-convert one or more of the antenna signals. The PDC simultaneously converts the phase-modulation into intensity modulation and converts the high RF carrier frequency into a more manageable lower frequency.

In another implementation an optical comb source can be used as the set of input wavelengths to the phase modulator-based ROAs, which allows conversion of differential phase to an amplitude using a single asymmetric Mach Zehnder Interferometer (AMZI) demodulator provided the delay of the AMZI matches or is some sub-multiple of the optical comb frequency spacing. A splitting device can allow two AMZI's of different free spectral range (FSR) to operate on any wavelength, thus broadening the RF bandwidth over which at least one AMZI will efficiently operate. The ROAs can then operate in different RF frequency bands, and depending on the RF frequency to be measured the appropriate AMZI can be used.

### BRIEF DESCRIPTION OF DRAWINGS

FIG. 1 shows a schematic block diagram of an apparatus for RF signal processing in accordance with a first exemplary embodiment of the invention;

FIG. 2 shows a schematic block diagram of an apparatus for RF signal processing in accordance with a second exemplary embodiment of the invention;

FIG. 3 shows a schematic block diagram of an apparatus for RF signal processing in accordance with a third exemplary embodiment of the invention; and

FIG. 4 shows a schematic block diagram of an apparatus for RF signal processing in accordance with a fourth exemplary embodiment of the invention.

### DETAILED DESCRIPTION

In the following description, for purposes of explanation, numerous specific details are set forth in order to provide a thorough understanding of the invention. It will be apparent, however, to one skilled in the art that the invention can be practiced without these specific details.

Reference in this specification to “one embodiment”, “an embodiment” or “first/second/third/fourth embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not to other embodiments. In general, features described in one embodiment might be suitable for use in other embodiments as would be apparent to those skilled in the art.

The word “exemplary” is used herein in the meaning of “used as an illustration”. Unless otherwise stated, any embodiment described herein as “exemplary” should not be construed as preferable or having an advantage over other embodiments.

Although the numerative terminology, such as “first”, “second”, etc., may be used herein to describe various embodiments, elements or features, these embodiments, elements or features should not be limited by this numerative terminology. This numerative terminology is used herein only to distinguish one embodiment, element or feature from another embodiment, element or feature. Thus, a first embodiment discussed below could be called a second embodiment, and vice versa, without departing from the teachings of the present disclosure.

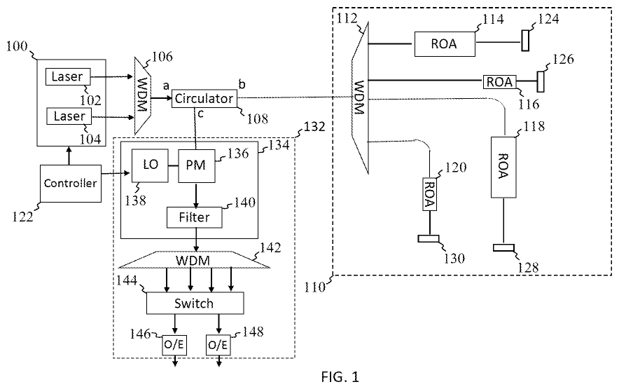

FIG. 1 shows a schematic block diagram of an apparatus for RF signal processing in accordance with a first exemplary embodiment of the invention. An optical source 100 consists of one or more tunable lasers, in this case a first tunable laser 102 and a second tunable laser 104. The lasers 102 and 104 have polarized outputs coupled into a polarization maintaining (PM) fiber, and are combined in a combining PM-WDM 106 so as to propagate together through an optical circulator 108. The optical circulator 108 transmits signals entering through input port a to common port b, and reflects signals entering through common port b into output port c. The signal transmitted from the optical circulator 108 goes to an RF-to-optical conversion system 110, which is implemented in a photonic integrated circuit (PIC). An antenna-selection wavelength division multiplexer (WDM) 112 splits the wavelengths from the fiber into a corresponding output port. For instance, an input wavelength of λ₁ is sent to WDM output port₁, an input wavelength of λ₂ is sent to WDM output port₂, and so on.

The RF-to-optical conversion system 110 consists of four RF-to-optical antennas (ROAs) with an ROA 114 designed to operate in a bandwidth of 20 GHz centered around an RF frequency f₁=42 GHz and an ROA 116 designed to operate in a bandwidth of 20 GHz centered around a frequency f₂=60 GHz. Both the ROAs 114 and 116 respond to RF signals of the same polarization, such as a horizontal polarization. By using the ROAs 114 and 116 with a partially-overlapping frequency response, the RF-to-optical conversion system 110 allows for measurement of RF signals over an extended range of frequencies, in this case from 32-70 GHz. The total bandwidth over which at least one of the ROAs 114 and 116 is sensitive is 38 GHz, which is more than 50% larger than the bandwidth of any one of the ROAs 114 and 116. By employing more than two ROAs, the range of frequencies over which at least one ROA will operate can be arbitrarily expanded, or multiple bands of RF frequencies can be measured where each band uses an ROA optimized for the particular frequency range of interest.

In this example, there are S=2 optical wavelengths probing the RF-to-optical conversion system 110 and N=4 selectable wavelengths, each wavelength probing a different ROA. The ROAs 114 and 116 are phase modulators that apply a phase shift to the probing optical signal in response to the incoming RF signal. As such they do not require an electrical bias signal and can be implemented in a completely passive PIC.

An ROA 118 is designed to operate in a bandwidth of 20 GHz centered around an RF frequency f₁=f₃=42 GHz and an ROA 120 is designed to operate in a bandwidth of 20 GHz centered around a frequency f₂=f₄=60 GHz. However, the ROAs 118 and 120 are designed to respond to a different RF polarization than the ROAs 114 and 116, such as a vertical polarization. This allows the RF-to-optical conversion system 110 to either measure unpolarized or unknown polarized input signals, or for different polarizations to be measured independently to allow for RF polarization multiplexing. In FIG. 1, the physical orientation of similarly designed ROAs determine the RF polarization to which they respond, with a 90-degree rotation of the antenna changing the optimal RF polarization from vertical to horizontal.

A system controller 122 programs the tunable lasers 102 and 104 to probe two different ROAs among the ROAs 114, 116, 118 and 120. For instance, the tunable lasers 102 and 104 will be tuned to λ₁ and λ₂ to probe the ROAs 114 and 116 if the goal is to measure RF signals of horizontal polarization at the RF frequencies of f₁ and f₂. However, the tunable lasers 102 and 104 will be tuned to λ₁ and λ₃ if the goal is to probe the antenna 114 and 118 to measure the RF frequencies of f₁ at both the horizontal and vertical polarization. By appropriately tuning the tunable lasers 102 and 104, any two of the ROAs 114, 116, 118 and 119 can be simultaneously probed, thereby measuring different RF signal characteristics. In general, there can be S wavelengths probing S of N possible ROAs, where N≥S.

The use of S>1 wavelengths allow for multiple RF signals to be measured simultaneously, where a different RF signal corresponds to a different property of the entire electromagnetic wave reaching the PIC which includes different frequencies, polarization, or spatial properties. However, it is possible for a single tunable laser to be used (i.e., S=1) to probe one of the ROAs 114, 116, 118 and 120 by tuning the wavelength of the tunable laser appropriately, thus allowing the receiver to choose one of the ROAs 114, 116, 118 and 120 to be probed, where the ROA selected determines the properties of the RF signal that are measured, such as its frequency and polarization. This method of selecting or demultiplexing a desired subset of signals to measure does not require an electrical selection signal to be sent to the RF-to-optical conversion system 110, since it is based on the wavelength of the optical source that is selected at the optical source (via the optical source wavelengths) which is separate from the RF-to-optical conversion system 110.

The optical signals after the antennas 114, 116, 118 and 120 are back-reflected using Bragg grating reflectors 124, 126, 128 and 130, respectively, after an appropriate delay, as is known in the art, so as to remodulate the optical signal at the chosen center-frequency, thus doubling the modulation depth. This propagates each optical wavelength back to the WDM 112 which recombines the wavelengths onto the same fiber at the input of the RF-to-optical conversion system 110 sending all the optical wavelengths back to the optical circulator 108.

The optical circulator 108 separates the reflected (modulated) signals, which are then sent to a signal processing unit 132. In the first exemplary embodiment, the signal processing unit 132 is implemented as follows. A photonic down-conversion system 134 consists of a phase modulator 136 driven by a tunable local-oscillator (LO) 138 and followed by a multiple-band notch filter 140 implemented as a Fabry Perot interferometer. The Fabry Perot interferometer has a periodic frequency response that blocks a narrow range of optical frequencies separated by a free spectral range (FSR) of f_{FSR} on a regular frequency grid. The system controller 122 selects a desired tunable LO frequency, where the desired LO frequency can change depending on the RF frequency or frequencies that are to be measured, which are also related to the optical wavelengths generated by the optical source 100.

For instance, f_{FSR} can be 200 GHz and the optical bandwidth Δf_{notch} of the notch filter 140, which can be defined as the optical bandwidth over which at least 3 dB loss is incurred on the transmitted optical signal, can be 10 GHz. The selectable laser wavelengths of λ₁₋₄ are all chosen to be on the regular frequency grid (separated by j·f_{FSR} where j is an integer) and thus the original wavelength from the optical source 100 do not pass through the multiple-wavelength notch filter 140. However, the portion of the carrier that was modulated by the LO 138 at f_{LO} or by an RF signal at f_{RF} via one of the ROAs does pass. This creates the down-converted optical signals at a lower intermediate frequency via mixing of f_{LO} and f_{RF}.

The signal transmitted from the notch filter 140 enters a channel-splitting WDM 142 which separates the four relevant wavelength bands centered at λ₁₋₄ into 4 outputs that are sent to an optical switch 144 that passes two of the input wavelength bands to two optical-to-electrical (O/E) detectors 146 and 148. The electrical output of the O/E detectors 146 and 148 represent the down-converted received RF signals of interest. The O/E electrically detected center frequencies are translated to a down-converted intermediate frequency (IF) of f_{IF}=f_{RF}±f_{LO}, where f_{RF} is the RF central frequency modulated onto the optical carrier by the respective antenna and f_{LO} is the LO frequency. The optical switch allows the number of O/E detectors to be reduced to two while still allowing any of the four possible relevant wavelength bands to be measured.

The down-conversion is accomplished when the bandwidth of the notch filter 140 is chosen so that min(f_{RF},f_{LO})>Δf_{notch}>|f_{RF}−f_{LO}| for any given wavelength channel and its corresponding RF signal. For instance, consider an incoming frequency of f₁=f₃=42 GHz, with the tunable lasers 102 and 104 tuned to λ₁ and λ₃. If one selects f_{LO}=40 GHz, then 40 GHz>10 GHz>2 GHz, and the incoming 42 GHz RF frequency is down-converted to f_{IF}=2 GHz after the O/E detectors 146 and 148. If instead the incoming RF frequency to be measured is in the range of f₂=f₄=60±3 GHz, then one can select f_{LO}=56 GHz which satisfies the equation over the full 6 GHz measurement band, generating intermediate frequencies between 1 and 7 GHz depending on the incoming RF frequency. This demonstrates the benefit of a tunable LO.

If the system is to simultaneously measure widely different carrier frequencies, then one solution is to use multiple LO/PM photonic down-conversion systems, sending the wavelength associated with the widely different carrier frequencies to different down-conversion systems that use different LO frequencies.

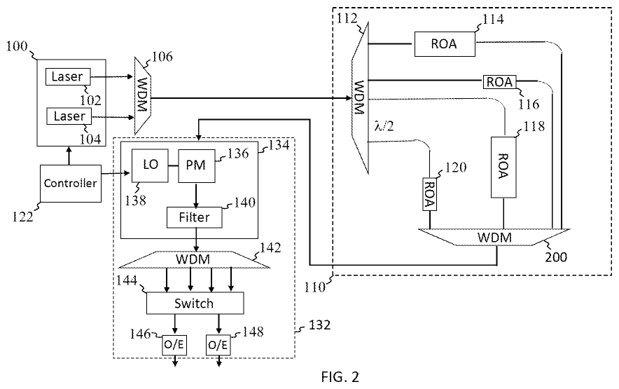

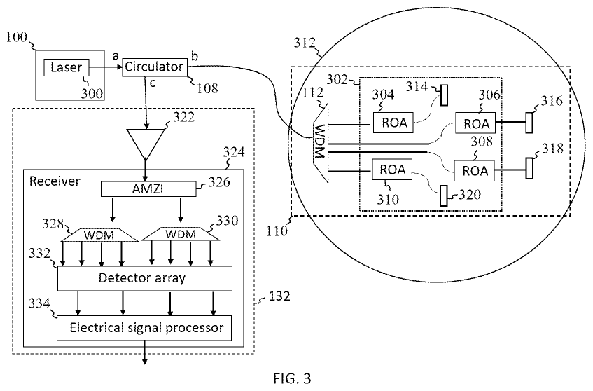

FIG. 2 shows a schematic block diagram of an apparatus for RF signal processing in accordance with a second exemplary embodiment of the invention. Components that are shared with FIG. 1 share the same numbering scheme. In general, the apparatus shown in FIG. 2 differs from the one shown in FIG. 1 in the way by which phase-modulated optical signals are transmitted from the ROAs 114, 116, 118 and 120 to the signal processing unit 132. More specifically, instead of the optical circulator 108 and the reflectors 124, 126, 128 and 130, there is an additional WDM 200 used in the RF-to-optical conversion system 110. The WDM 200 has outputs each coupled to one of the ROAs 114, 116, 118 and 120. When the WDM 200 receives the phase-modulated optical signals from the ROAs 114, 116, 118 and 120, it combines them into a combined phase-modulated optical signal which is transmitted through the input port of the WDM 200 to the signal processing unit 132. The combined phase-modulated optical signal is processed in the signal processing unit 132 in the same way as discussed above with reference to FIG. 1. FIG. 3 shows a schematic block diagram of an apparatus for RF signal processing in accordance with a third exemplary embodiment of the invention. Again, components that are shared with FIG. 1 share the same numbering scheme. The optical source 100 is a comb source (e.g., a mode-locked laser) 300 producing multiple optical tones (spectral frequencies or equivalently wavelengths) at a precise frequency separation of Δf_{comb}=50 GHz. In this case, we are concerned with the four tones that match the antenna-selection WDM 112. The comb lines propagate through the optical circulator 108 to the RF-to-optical conversion system 110, which is realized in a thin film lithium niobate photonic integrated circuit (PIC). The RF-to-optical conversion system 110 contains the antenna-selection WDM 112 that splits the relevant wavelengths from the fiber into a corresponding output port on the antenna-selection WDM 112, so that each ROA is probed by a different comb tone. The RF signal hitting a quad array 302 of ROAs 304, 306, 308 and 310 is phase-modulated onto the underlying optical signal probing the respective ROA. Each ROA in the third exemplary embodiment have nominally the same RF spectral response and the same RF polarization sensitivity, but detect a different property of the incoming RF field due to their different spatial position.

As noted above, the ROAs are arranged in an array, which here is the quad array 302 which can be grouped into upper detector pairs 304 and 306, lower detector pairs 308 and 310, left detector pairs 304 and 310, and right detector pairs 306 and 308. An electro-magnetic lens 312 sits above the plane of the PIC by the focal length of the lens. The lens 312 focuses the incoming wireless RF signal onto the quad array 302 of ROAs, and the relative strength of the signal on each ROA is related to the angle-of-arrival of the RF signal. For instance, an RF signal arriving along the central axis of the lens will be focused in the center of the quad formation so that each ROA detects the same size signal, but an RF signal traveling at an angle from right-to-left (looking at the PIC plane) will preferentially strike the left detector pairs. Thus, the relative measured RF intensity on each of the detectors reveals information about the angle-of-arrival of the RF signal, as is known in the art.

After propagating through their respective ROAs, the optical signals are reflected back through the ROAs by Bragg grating reflectors 314, 316, 318 and 320, recombined by the antenna-selection WDM 112, and split off by the reflection port of the optical circulator 108. The reflected port of the optical circulator 108 is amplified by a fiber amplifier 322. The gain of the amplifier 322 increases the intensity of all the comb lines, which helps to increase the size of the received RF signal, although the fiber amplifier 322 adds unwanted relative intensity noise. However, the added relative intensity noise will eventually be largely removed by the action of a balanced detection system included in the signal processing unit 132, making the fiber amplifier 322 advantageous.

The output of the fiber amplifier 322 is sent to a receiver 324. The receiver 324 consists of a periodic filter realized in an AMZI 326 that has a free spectral range Δf_{AMZI} that is a sub-multiple of the comb FSR, such that q·Δf_{AMZI}=Δf_{comb}, where q is a positive integer. This allows each comb line to simultaneously be properly biased in the AMZI 326, where the bias is typically chosen such that the absence of an RF signal leads to 50/50 splitting of the comb lines onto both of the AMZI output ports. This configuration forces the optical intensity of the two AMZI output ports to respond in opposite direction to the phase modulation from an RF signal, such that the size of the difference between the signal output from both AMZI arms is enhanced but common-mode intensity noise, such as relative intensity noise, affects both AMZI outputs in the same way so that the difference between the AMZI signal outputs subtracts out the intensity variations and reduces unwanted common-mode noise. The method described allows all the comb tones to simultaneously achieve this desired bias condition.

The comb lines out of each AZMI output port are separated using post-demodulation WDMs 328 and 330. Each of the demodulation WDM outputs is detected in a different optical-to-electrical detector of a balanced detector array 332. The balanced detector array 332 contains a pair of balanced detectors for each optical wavelength, where the current from the two detectors lit by the same wavelength is subtracted in order to realize the balanced detection function, as is known in the art. This produces four electrical outputs, one for each comb line that is modulated with the RF signal hitting the corresponding antenna, and subsequent signal processing can be performed in an electronic signal processor 334 in order to determine the angle-of-arrival of the received RF signal, as is known in the art.

To achieve strong gain, the received RF signal should be contained within a frequency bandwidth of Δf_{AMZI}/2 and have a nominal central frequency of f_{RF}=(z+1/2)·Δf_{AMZI}, where z is an integer. All the constraints can be met, for example, using f_{RF}=(25±12.5) GHz, Δf_{comb}=50 GHz, Δf_{AMZI}=50 GHz (q=1). A single AMZI can then function as a phase-to-intensity converter for multiple comb lines, since each successive optical comb tooth (wavelength) is biased the same way in the AMZI.

If the RF frequency of interest is outside the range of f_{RF}=(25±12.5) GHz, which arises from setting z=0 then the same AMZI can still be used for higher RF frequencies of (3/2)·50 GHz. This allows a large number of discrete bands of measurable frequencies with a single AMZI, however it does not allow for near-continuous frequency measurement.

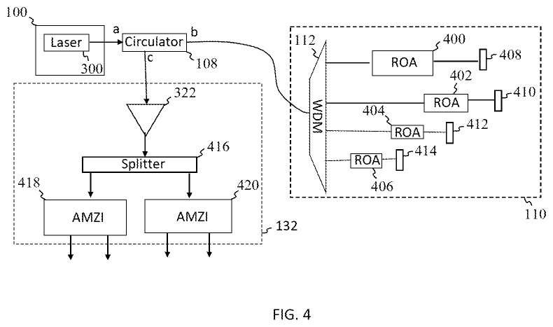

FIG. 4 shows a schematic block diagram of an apparatus for RF signal processing in accordance with a fourth exemplary embodiment of the invention. In particular, FIG. 4 shows a modified configuration that allows for a wide-band measurement over a broad and continuous spectral band greater than Δf_{AMZI}/2. Each of four ROAs 400, 402, 404 and 406 are optimized for operation in a different frequency band. As before, the phase-modulated optical signals after the ROAs 400, 402, 404 and 406 are reflected by Bragg grating reflector 408, 410, 412 and 414, respectively. The signals are multiplexed by the antenna selection WDM 112, and separated by the optical circulator 108. The comb line spacing is now set to Δf_{comb}=100 GHz

Assuming each of the ROAs 400, 402, 404 and 406 has a relative bandwidth ±20% of the nominal frequency, the ROAs can have frequency bands of (20±4) GHz, (30±6) GHz, (40±8) GHz, and (60±12) GHz. With this design, at least one of the ROAs 400, 402, 404 and 406 responds to every frequency in the continuous range between 16 GHz to 72 GHz. The multiplexing of multiple ROAs of different frequency responses allows the net frequency response of the RF-to-optical conversion system 110 to be much wider than any individual ROA. In this case, each individual ROA's frequency response spans a relative ratio fₘₐₓ/fₘᵢₙ=1.5, where the net system response spans a relative ratio of 72/16=4.5. It is usually difficult to design a single antenna with both high efficiency and more than an octave of bandwidth (fₘₐₓ/fₘᵢₙ>2), but multiplexing avoids this problem for the net system. The use of multiple ROAs allows for a net system bandwidth that is at least 50% larger than the bandwidth of any single RF to optical phase modulator. In this case, the largest ROA bandwidth is 24 GHz and the net system bandwidth is 56 GHz which leads to more than a factor of 2 (>100%) wider system level bandwidth.

The multiplexed signals are amplified in the fiber amplifier 322 and sent to a splitting device 416, which can be realized as a simple 50/50 optical splitter. The outputs of the splitting device 416 are sent to two periodic filters realized as a first AMZI 418 and a second AMZI 420. The first AMZI 418 has a free spectral range of Δf_{AMZI}=50 GHz, or q=2, making it sensitive to frequencies from (12.5-37.5) GHz and (62.5-87.5) GHz. It thus has a low responsivity range between (37.5-62.5) GHz (at 50 GHz it has a blind spot with no responsivity). The second AMZI 420 has free spectral range of Δf_{AMZI}=k·Δf_{comb}=100 GHz, where k is an integer not equal to q and here k=1. This choice gives the second AMZI responsivity range of 50±25 GHz, or from 25-75 GHz. Thus, the use of the second AMZI 420 with a different free spectral range than the first AMZI 418 enables the measurement over a large and continuous RF spectral range, at least from 12.5 GHz to 87.5 GHz (neglecting the ROA frequency response, which can be arbitrarily increased by using more antennas).

The splitting device 416 could also be a wavelength-sensitive splitter which can separate different wavelengths to different outputs and has the advantage of less inherent insertion loss. The simple 50/50 splitter sends all the comb lines to both the splitter outputs which feed the first and second AMZIs 418 and 420, making it possible to use either AMZI to measure the RF modulation on any of the comb lines. The 50/50 splitter design thus gives lots of flexibility in that the frequency bandwidth over which an antenna responds to RF signals does not need to be confined to the frequency bandwidth of just one of the AMZIs 418 and 420. That is, a given ROA may be phase-to-amplitude converted by either AMZI depending on what RF frequency is of interest. Another solution would be the use of a programmable filter as the splitting device, as this would allow the optical spectral profile sent to each AMZI to be re-programmed as desired, so that any wavelength could be sent to either AMZI. However, while flexible such a system typically has higher insertion loss and is more expensive than the simpler solutions previously described.

Foregoing described embodiments of the invention are provided as illustrations and descriptions. They are not intended to limit the invention to precise form described. In particular, it is contemplated that functional implementation of invention described herein may be implemented equivalently in other available functional components or building blocks. Other variations and embodiments are possible in light of above teachings, and it is thus intended that the scope of invention not be limited by this.

What is claimed is:

1-20. (canceled)

21. An apparatus for radio frequency (RF) signal processing, comprising:
an optical source configured to emit an optical signal, the optical signal having a wavelength and a phase;
a wavelength division multiplexer (WDM) coupled to the optical source, the WDM having an input port and at least two output ports, the WDM being configured to receive the optical signal at the input port and direct the optical signal to one of the at least two output ports based on the wavelength of the optical signal;
at least two RF-to-optical antennas (ROAs) each coupled to one of the at least two output ports of the WDM, each of the at least two ROAs being a phase modulator that is configured to: (i) receive an RF signal; (ii) produce a phase-modulated optical signal by modulating the phase of the optical signal with the RF signal; and (iii) output the phase-modulated optical signal; and
a signal processing unit configured to receive the phase-modulated optical signal from one of the at least two ROAs and retrieve the RF signal from the phase-modulated optical signal.

22. The apparatus of claim 21, further comprising an additional WDM having at least two input ports and an output port, each of the at least two input ports of the additional WDM being coupled to one of the at least two ROAs, the additional WDM being configured to receive the phase-modulated optical signal at one of the at least two input ports and direct the phase-modulated optical signal to the output port, and the signal processing unit being coupled to the output port of the additional WDM.

23. The apparatus of claim 21, further comprising:
an optical circulator (OC) having an OC input port, an OC common port and an OC output port, the OC input port being coupled to the optical source, the OC common port being coupled to the input port of the WDM, the OC output port being coupled to the signal processing unit, the OC being configured to receive the optical signal at the OC input port and direct the optical signal to the OC common port; and
at least two reflectors each coupled to one of the at least two ROAs, each of the at least two reflectors being configured to reflect the phase-modulated optical signal towards the WDM;
wherein the WDM is further configured to receive the phase-modulated optical signal reflected by one of the at least two reflectors at one of the at least two output ports of the WDM and direct the phase-modulated optical signal to the input port of the WDM; and
wherein the OC is further configured to receive the phase-modulated optical signal at the OC common port and direct the phase-modulated optical signal to the OC output port.

24. The apparatus of claim 23, wherein each of the at least two reflectors is configured as a Bragg grating reflector.

25. The apparatus of claim 21, wherein the WDM and the at least two ROAs are implemented in a single photonic integrated circuit (PIC).

26. The apparatus of claim 25, further comprising an electro-magnetic lens arranged above the PIC and configured to focus the RF signals onto the at least two ROAs.

27. The apparatus of claim 21, wherein the signal processing unit comprises:
a down-conversion subunit configured to down-convert the phase-modulated optical signal; and
an optical-to-electrical (O/E) conversion subunit configured to retrieve the RF signal from the down-converted phase-modulated optical signal by using an O/E conversion.

28. The apparatus of claim 27, wherein the down-conversion subunit comprises a periodic filter.

29. The apparatus of claim 27, wherein the signal processing unit further comprises an amplification subunit configured to amplify the phase-modulated optical signal before the phase-modulated optical signal is down-converted by the down-conversion subunit.

30. The apparatus of claim 22,
wherein the at least two output ports of the WDM comprises a first output port and a second output port, the at least two input ports of the additional WDM comprises a first input port and a second input port, and the at least two ROAs comprise a first ROA coupled to the first output port of the WDM and a second ROA coupled to the second output port of the WDM;
wherein the optical source is further configured to emit an additional optical signal, the additional optical signal having a wavelength and a phase;
wherein the WDM is configured to receive the optical signal and the additional optical signal at the input port and direct the optical signal to the first output port and the additional optical signal to the second output port based on the wavelength of each of the optical signal and the additional optical signal;
wherein the first ROA is configured to produce a first phase-modulated optical signal by modulating the phase of the optical signal with a first RF signal, and the second ROA is configured to produce a second phase-modulated optical signal by modulating the phase of the additional optical signal with a second RF signal;
wherein the additional WDM is configured to: (i) receive the first phase-modulated optical signal at the first input port and the second phase-modulated optical signal at the second input port; (ii) combine the first phase-modulated optical signal and the second phase-modulated optical signal into a combined phase-modulated optical signal; and (iii) direct the combined phase-modulated optical signal to the output port; and
wherein the signal processing unit is configured to receive the combined phase-modulated optical signal from the output port of the additional WDM and retrieve the first RF signal and the second RF signal from the combined phase-modulated optical signal.

31. The apparatus of claim 21, wherein the signal processing unit comprises:
a splitting subunit configured to split the combined phase-modulated optical signal into a first phase-modulated optical sub-signal and a second phased-modulated optical sub-signal; and
a first phase-to-amplitude conversion subunit configured to convert the first phase-modulated optical sub-signal to a first amplitude-modulated optical sub-signal, the first phase-to-amplitude conversion subunit having a first frequency response characteristic;
a second phase-to-amplitude conversion subunit configured to convert the second phase-modulated optical sub-signal to a second amplitude-modulated optical sub-signal, the second phase-to-amplitude conversion subunit having a second frequency response characteristic different from the first frequency response characteristic; and
an O/E conversion subunit configured to retrieve the first RF signal from the first amplitude-modulated optical sub-signal and the second RF signal from the second amplitude-modulated optical sub-signal by using an O/E conversion, each of the retrieved first RF signal and the retrieved second RF signal having a different RF frequency.

32. The apparatus of claim 31, wherein each of the first phase-to-amplitude conversion subunit and the second phase-to-amplitude conversion subunit comprises a periodic filter.

33. The apparatus of claim 21, wherein the signal processing unit further comprises an amplification subunit configured to amplify the combined phase-modulated optical signal before the combined phase-modulated optical signal is split in the splitting subunit.

34. The apparatus of claim 33,
wherein the at least two output ports of the WDM comprises a first output port and a second output port, the at least two ROAs comprise a first ROA coupled to the first output port of the WDM and a second ROA coupled to the second output port of the WDM, and the at least two reflectors comprise a first reflector coupled to the first ROA and a second reflector coupled to the second ROA;
wherein the optical source is further configured to emit an additional optical signal, the additional optical signal having a wavelength and a phase;
wherein the WDM is configured to receive the optical signal and the additional optical signal at the input port and direct the optical signal to the first output port and the additional optical signal to the second output port based on the wavelength of each of the optical signal and the additional optical signal;
wherein the first ROA is configured to produce a first phase-modulated optical signal by modulating the phase of the optical signal with a first RF signal, and the second ROA is configured to produce a second phase-modulated optical signal by modulating the phase of the additional optical signal with a second RF signal;
wherein the first reflector is configured to reflect the first phase-modulated optical signal towards the first output port of the WDM, and the second reflector is configured to reflect the second phase-modulated optical signal towards the second output port of the WDM;
the WDM is configured to: (i) receive the first phase-modulated optical signal at the first output port and the second phase-modulated optical signal at the second output port; (ii) combine the first phase-modulated optical signal and the second phase-modulated optical signal into a combined phase-modulated optical signal; and (iii) direct the combined phase-modulated optical signal to the input port;
wherein the optical circulator is configured to receive the combined phase-modulated optical signal at the OC common port and direct the combined phase-modulated optical signal to the OC output port; and
wherein signal processing unit configured to receive the combined phase-modulated optical signal from the OC output port and retrieve the first RF signal and the second RF signal from the combined phase-modulated optical signal.

35. The apparatus of claim 34, wherein the signal processing unit comprises:
a splitting subunit configured to split the combined phase-modulated optical signal into a first phase-modulated optical sub-signal and a second phased-modulated optical sub-signal;
a first phase-to-amplitude conversion subunit configured to convert the first phase-modulated optical sub-signal to a first amplitude-modulated optical sub-signal, the first phase-to-amplitude conversion subunit having a first frequency response characteristic;
a second phase-to-amplitude conversion subunit configured to convert the second phase-modulated optical sub-signal to a second amplitude-modulated optical sub-signal, the second phase-to-amplitude conversion subunit having a second frequency response characteristic different from the first frequency response characteristic; and
an O/E conversion subunit configured to retrieve the first RF signal from the first amplitude-modulated optical sub-signal and the second RF signal from the second amplitude-modulated optical sub-signal, each of the retrieved first RF signal and the retrieved second RF signal having a different RF frequency.

36. The apparatus of claim 35, wherein each of the first phase-to-amplitude conversion subunit and the second phase-to-amplitude conversion subunit comprises a periodic filter.

37. The apparatus of claim 35, wherein the signal processing unit further comprises an amplification subunit configured to amplify the combined phase-modulated optical signal before the combined phase-modulated optical signal is split in the splitting subunit.

38. The apparatus of claim 21, wherein each of the at least two ROAs is configured to operate in a different range of operational RF frequencies.

39. The apparatus of claim 21, wherein each of the at least two ROAs is sensitive to a different polarization type of RF signals.

40. An apparatus for radio frequency (RF) signal processing, comprising:
an optical source configured to emit an optical signal, the optical signal having a wavelength;
a wavelength division multiplexer (WDM) coupled to the optical source, the WDM having an input port and two output ports, the WDM being configured to receive the optical signal at the input port and direct the optical signal to one of the two output ports based on the wavelength of the optical signal;
two RF-to-optical antennas (ROAs) each coupled to one of the two output ports of the WDM, each of the two ROAs configured to: (i) receive an RF signal; (ii) modulate the optical signal with the RF signal; and (iii) output the modulated optical signal, one of the two ROAs being operable in a first RF band and another of the two ROAs being operable in a second RF band different from the first RF band; and
a signal processing unit configured to receive the modulated optical signal from one of the two ROAs and retrieve the RF signal from the modulated optical signal;
wherein the apparatus further comprises:
an optical circulator (OC) having an OC input port, an OC common port and an OC output port, the OC input port being coupled to the optical source, the OC common port being coupled to the input port of the WDM, the OC output port being coupled to the signal processing unit, the OC being configured to receive the optical signal at the OC input port and direct the optical signal to the OC common port; and
two reflectors each coupled to one of the two ROAs, each of the two reflectors being configured to reflect the modulated optical signal towards the WDM;
wherein the WDM is further configured to receive the modulated optical signal reflected by one of the two reflectors at one of the two output ports of the WDM and direct the modulated optical signal to the input port of the WDM; and
wherein the OC is further configured to receive the modulated optical signal at the OC common port and direct the modulated optical signal to the OC output port;
wherein the retrieved RF signal has a frequency band determined by the wavelength of the optical signal.
